(19) United States
(12) Patent Application Publication
(10) Pub. No.: US 2021/0410304 A1
(43) Pub. Date: Dec. 30, 2021

(54) ELECTRONIC DEVICE HOUSING AND FIXING BRACKET

(71) Applicant: HONGFUJIN PRECISION ELECTRONICS(TIANJIN)CO.,LTD., Tianjin (CN)

(72) Inventors: WEN-HU LU, Tianjin (CN); LI-YI YIN, Tianjin (CN)

(21) Appl. No.: 16/934,830

(22) Filed: Jul. 21, 2020

(30) Foreign Application Priority Data
Jun. 24, 2020 (CN) 202010591930.4

(51) Int. Cl. H05K 5/02

(52) U.S. Cl. CPC H05K 5/0204; H05K 7/20136

(57) ABSTRACT

A fixing bracket includes a connecting plate, a top plate, and two side plates. The two side plates are parallel to each other and cooperatively define an accommodating space with the top plate and the connecting plate. The connecting plate, the top plate, and the two side plates are integrally formed. A cutout is defined in at least one of the connecting plate and the top plate for passing through a clamping spring.

### FIELD

The subject matter herein generally relates to fixing brackets, and more particularly to a fixing bracket for an electronic device housing.

### BACKGROUND

In today's computer server systems, hot-swapping refers to the direct insertion and removal of system components when the system is powered on, so that the system can operate normally without interruption. The fan is a crucial component which often needs to be hot-swapped. In the related art, a fan bracket is generally assembled from three or four complex parts, which has problems of high cost, difficult assembly, and poor stability.

### BRIEF DESCRIPTION OF THE DRAWINGS

Implementations of the present disclosure will now be described, by way of embodiments, with reference to the attached figures.

FIG. 1 is an overall schematic diagram of an electronic device housing according to an embodiment.

FIG. 2 is an overall schematic diagram of a fixing bracket according to an embodiment.

FIG. 3 is a partial exploded view of the fixing bracket.

FIG. 4 is an overall schematic view of the fixing bracket shown from another perspective.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

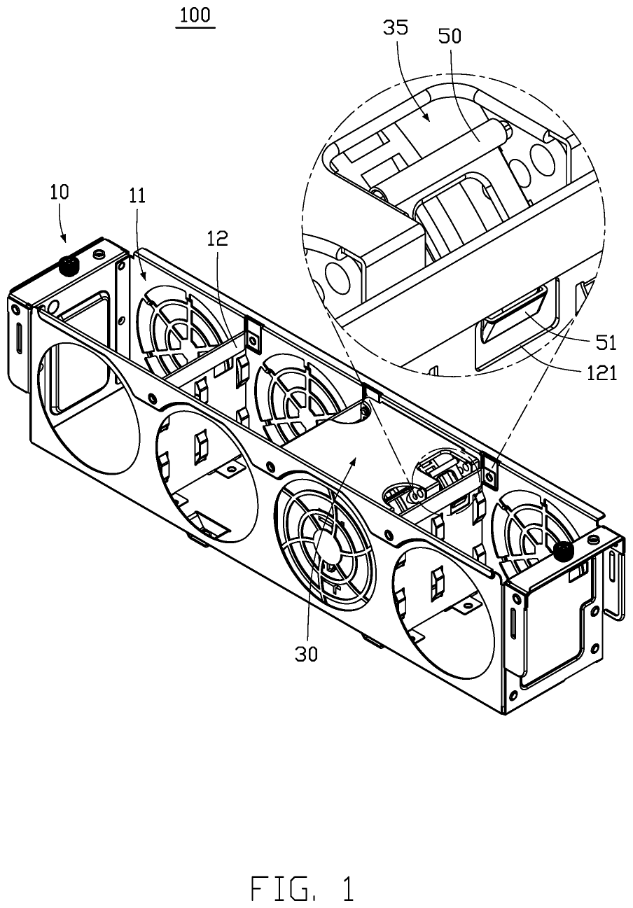

Referring to FIG. 1, an electronic device housing 100 includes a frame 10, at least one fixing bracket 30, and at least one clamping spring 50. The clamping spring 50 fixes the fixing bracket 30 on the frame 10. In one embodiment, the electronic device housing 100 is used to fix at least one fan.

The frame 10 defines a receiving space 11, and a plurality of baffle plates 12 is located in the receiving space 11. The plurality of baffle plates 12 provided in the receiving space 11 divides the receiving space 11 into a plurality of storage spaces, and the fixing bracket 30 is fixed in one of the storage spaces. In one embodiment, the frame 10 is a rectangular parallelepiped shape, the number of the baffle plates 12 is three, and the three baffle plates 12 are arranged along a length of the receiving space 11. A slot 121 is defined in the baffle plate 12 for fixing the clamping spring 50. In one embodiment, the frame 10 has an open top, and both sides of the frame 10 in the longitudinal direction are hollowed out.

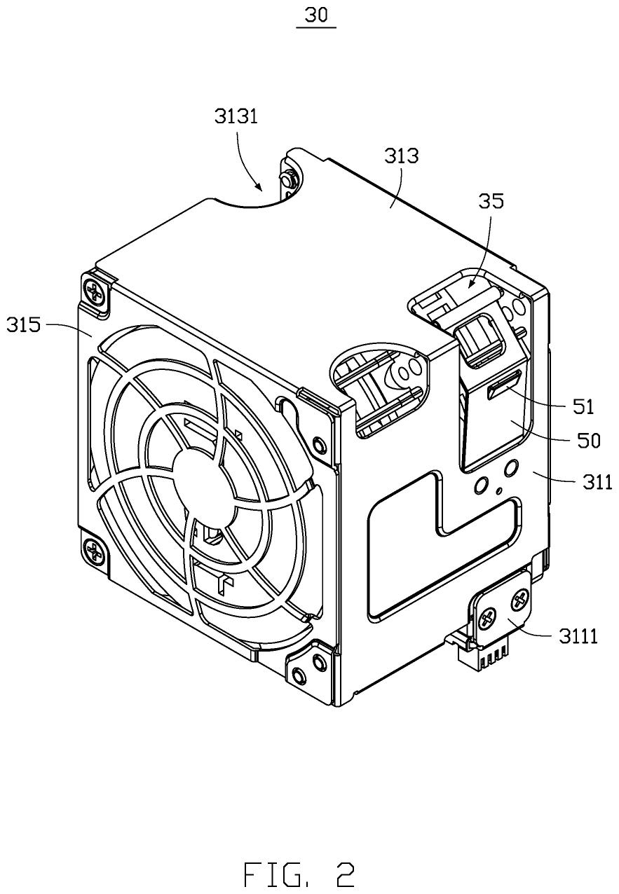

Referring to FIGS. 2-4, the fixing bracket 30 includes a plurality of plate bodies 31 and defines a cutout 35 and an accommodating space 33. The cutout 35 is defined at a joint between two adjacent plate bodies 31. In one embodiment, the plurality of plate bodies 31 includes a connecting plate 311, a top plate 313, and two side plates 315. The connecting plate 311 is parallel to the baffle plates 12. In one embodiment, the connecting plate 311 and the baffle plate 12 are attached to each other, the top plate 313 is perpendicular to the connecting plate 311, and the two side plates 315 are respectively located on two sides of the connecting plate 311 and connected to the top plate 313. In one embodiment, the two side plates 315 are parallel to each other. In one embodiment, the plate body 31 is a rectangular plate. The two side plates 315, the top plate 313, and the connecting plate 311 may be integrally formed by riveting an iron piece.

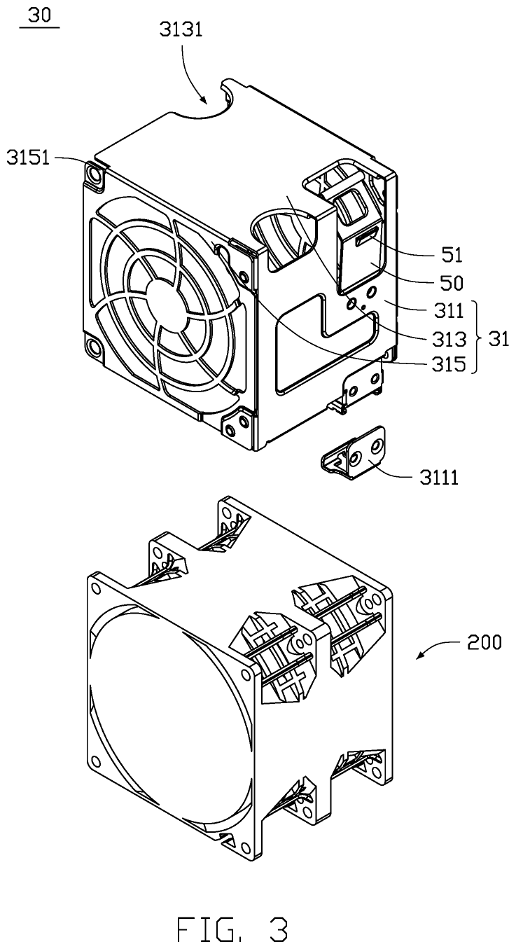

Referring to FIG. 3, a connector bracket 3111 is provided on a side of the connecting plate 311 facing away from the top plate 313, the connector bracket 3111 is used to fix a connector. In one embodiment, a cross-sectional shape of the connector bracket 3111 is substantially L-shaped. One side of the connector bracket 3111 is fixed to the connecting plate 311 by bolts, and another side of the connector bracket 3111 is hollowed out for passing through the connector. The top plate 313 is provided with a grabbing position 3131, which is formed by a recess in an edge of the top plate 313 to facilitate grabbing the fixing bracket 30. In one embodiment, the grabbing position 3131 is located on two sides of the top plate 313 perpendicular to the side plate 315. In one embodiment, the side plate 315 is fixed to the sides of the top plate 313 and the connecting plate 311 by fixing bolts. The two side plates 315 are used for fixing objects located in the fixing bracket 30. Each of the two side plates 315 defines a through hole 3151 penetrating the side plate 315 for passing through bolts to fix objects located in the fixing bracket 30. In one embodiment, the side plate 315 is substantially a hollow structure.

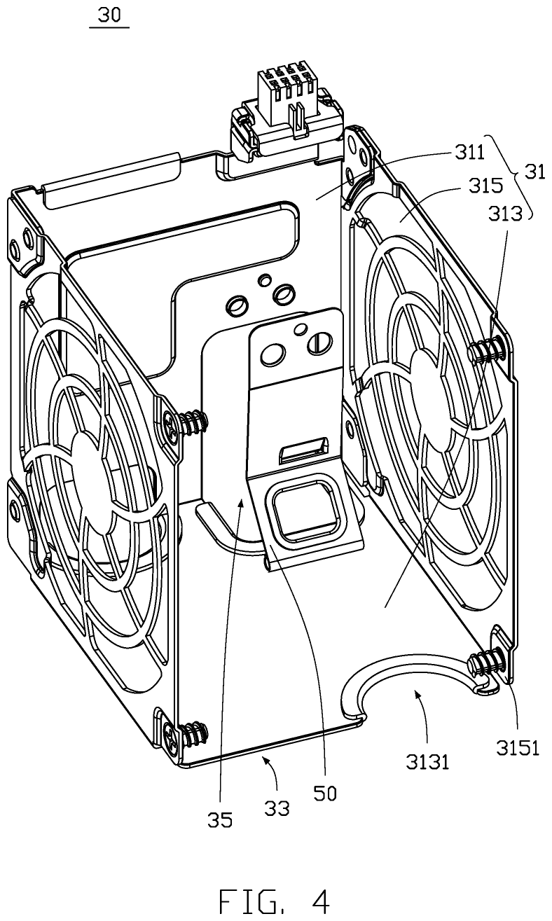

Referring to FIG. 4, the cutout 35 is defined at a joint between the connecting plate 311 and the top plate 313. The clamping spring 50 is fixed in the cutout 35.

The clamping spring 50 is fixed on the fixing bracket 30. In one embodiment, the clamping spring 50 is located at the joint between the connecting plate 311 and the top plate 313. The clamping spring 50 includes a pressable clamping portion 51. When the fixing bracket 30 is fixed on the frame 10, the clamping portion 51 is clamped in the slot 121 on the baffle plate 12. In one embodiment, a material of the clamping spring 50 is stainless steel.

In assembly, the integrally formed the two side plates 315, the top plate 313, and the connecting plate 311 are bent along the edges, and the two side plates 315 are connected and fixed on both sides of the top plate 313 and the connecting plate 311 by fixing bolts to form the fixing bracket 30. An object to be fixed is placed inside the fixing bracket 30, and bolts are inserted through the through holes 3151 of the two side plates 315 to fix the object. The fixing bracket 30 is installed in the corresponding storage space in the frame 10, and the clamping spring 50 fixes the fixing bracket 30 on the frame 10 to complete fixing the object. In one embodiment, the object is a fan.

The electronic device housing 100 is formed by the fixing bracket 30 mounted on the frame 10. The fixing bracket 30 is integrally formed from one metal piece or plastic piece and assembled by bolts with a low cost, simple structure, easy installation, and strong structural stability.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A fixing bracket comprising:
a connecting plate;
a top plate; and
two side plates parallel to each other and coupled to the top plate and the connecting plate, the connecting plate, the top plate, and the two side plates cooperatively defining an accommodating space; wherein:
the connecting plate, the top plate, and the two side plates are integrally formed; and
a cutout is defined in at least one of the connecting plate and the top plate.

2. The fixing bracket of claim 1, wherein:
each of the two side plates defines a through hole.

3. The fixing bracket of claim 1, wherein:
the top plate is provided with two grabbing positions formed by a recess in each of two sides of the top plate perpendicular to the sides of the top plate coupled to the side plates.

4. The fixing bracket of claim 1, wherein:
a connector bracket is provided on a side of the connecting plate facing away from the top plate.

5. The fixing bracket of claim 4, wherein:
a cross-sectional shape of the connector bracket is L-shaped;
one side of the connector bracket is fixed to the connecting plate by bolts, and another side of the connector bracket is hollowed out.

6. An electronic device housing comprising:
a frame defining a receiving space;
a plurality of baffle plates located in the receiving space and dividing the receiving space into a plurality of storage spaces along a lengthwise direction of the frame; and
at least one fixing bracket configured to be fixed in a corresponding one of the plurality of storage spaces.

7. The electronic device housing of claim 6, wherein:
the at least one fixing bracket comprises a connecting plate, a top plate, and two side plates parallel to each other and coupled to the top plate and the connecting plate;
the connecting plate, the top plate, and the two side plates cooperatively define an accommodating space.

8. The electronic device housing of claim 7, further comprising a clamping spring comprising a pressable clamping portion, wherein:
the connecting plate, the top plate, and the two side plates are integrally formed;
a cutout is defined in at least one of the connecting plate and the top plate for passing through the clamping spring; and
each of the plurality of baffle plates defines a slot for engaging with the clamping spring for fixing the at least one fixing bracket on the frame.

9. The electronic device housing of claim 8, wherein:
each of the two side plates defines a through hole.

10. The electronic device housing of claim 9, wherein:
the top plate is provided with two grabbing positions formed by a recess in each of two sides of the top plate perpendicular to the sides of the top plate coupled to the side plates.

11. The electronic device housing of claim 10, wherein:
a connector bracket is provided on a side of the connecting plate facing away from the top plate.

12. The electronic device housing of claim 11, wherein:
a cross-sectional shape of the connector bracket is L-shaped;
one side of the connector bracket is fixed to the connecting plate by bolts, and another side of the connector bracket is hollowed out.

13. The electronic device housing of claim 12, wherein:
the frame has an open top, and both sides of the frame in the lengthwise direction are hollowed out.

14. The electronic device housing of claim 13, wherein:
the connecting plate of the at least one fixing bracket is attached to a corresponding one of the plurality of baffle plates; and
the top plate of the at least one fixing bracket is located toward the open top of the frame.
